(19) United States
(12) Patent Application Publication
(10) Pub. No.: US 2012/0160300 A1
(43) Pub. Date: Jun. 28, 2012

(54) CONCENTRATED SPECTRALLY SEPARATED MULTICONVERTER PHOTOBOLTAIC SYSTEMS AND METHODS THEREOF

(75) Inventor: James F. Munro, Webster, NY (US)

(73) Assignee: REFLEXITE CORPORATION, AVON, CT (US)

(21) Appl. No.: 13/260,879

(22) PCT Filed: Mar. 31, 2010
(86) PCT No.: PCT/US10/29309

§ 371 Date: Mar. 13, 2012

Related U.S. Application Data
(60) Provisional application No. 61/165,129, filed on Mar. 31, 2009.

(51) Int. Cl. H01L 31/052

(52) U.S. Cl. 136/246

(57) ABSTRACT

A solar conversion apparatus and method includes two or more conversion cells and a reflector assembly. Each of the two or more solar conversion cells is responsive to a different one of at least a first band of wavelengths from solar radiation and a second band of wavelengths from the solar radiation. The reflector assembly comprises at least two integrated reflective sections. One of the at least two reflective sections is positioned to reflect and direct the first band of wavelengths towards one of the two or more solar conversion cells and another one of the at least two reflective sections is positioned to reflect and direct the second band of wavelengths towards another one of the two or more solar conversion cells. At least one of the two integrated reflective structures further comprises a Fresnel microstructure.

This application claims the benefit of U.S. Provisional Patent Application Ser. No. 61/165,129, filed Mar. 31, 2009, which is hereby incorporated by reference in its entirety.

### FIELD

This invention generally relates to photovoltaic converters and, more particularly, to concentrated solar photovoltaic converters.

### BACKGROUND

Optical concentrators are widely used in solar photovoltaic converters for two important reasons. First, they allow for reduced system cost because less photovoltaic conversion material is required which is by far the most expensive component in a photovoltaic system. Typically, concentrated photovoltaic systems have a photovoltaic cell that has less than 1% of the area of a photovoltaic cell used in an equivalent conversion apparatus. Second, it is well known that photovoltaic cells illuminated by higher flux densities achieve higher solar-to-electricity conversion efficiencies.

A typical prior art concentrating photovoltaic system 10 is illustrated in FIG. 1. The concentrating photovoltaic system 10 includes a condensing Fresnel lens 2 and a photovoltaic cell 4 located at the focal point 5 of the condensing Fresnel lens 2. Both the condensing Fresnel lens 2 and the photovoltaic cell 4 share a common optical axis 1. In operation, solar radiation 22 is incident on the condensing Fresnel lens 2 which causes the solar radiation 22 to be condensed and brought to a focus at a focal point 5 on the photovoltaic cell 4.

A Fresnel optical element can be of two types: one that operates in transmission which is called a Fresnel lens; and one that operates in reflection which is called a Fresnel mirror or Fresnel reflector. Both Fresnel lenses and Fresnel reflectors are commonly employed in solar concentrators and both include a Fresnel microstructure with a series of rather shallow grooves that are generally sawtooth in cross-section. The longer surface of each groove that performs the optical work is called the slope surface and the shorter surface that connects the slope surfaces together is called the draft or riser surface. The angle of the slope surface generally changes slightly from groove to groove being more shallow near the center of the Fresnel and steeper at the edges. At the same time the depth of the draft or riser surface are smaller near the center of the Fresnel microstructure and greater at the edge.

There are two major problems with this prior art concentrating photovoltaic system 10. First, the focal point 5 is not a point because of chromatic aberration. Instead, the focal point can be several centimeters in diameter depending on the geometry of the optical configuration and the range of wavelengths passed by the Fresnel lens 2. An ideal condensing Fresnel lens would transmit and bring to a focus all optical energy within the wavelengths of the sun that contain significant amounts of energy. Typically, the wavelengths of the sun range from about 350 nm to about 1900 nm. The dispersive nature of the material comprising the condensing Fresnel lens 2 causes the refractive index of the material to vary significantly over this range, which in turn causes the optical power of the condensing Fresnel lens 2 to vary as a function of wavelength, which in turn causes the diameter of the focal spot 5 to also vary with wavelength. To compensate for this, additional condensing optics can be installed atop the photovoltaic cell 4 or the photovoltaic cell 4 can be made substantially larger to ensure that it captures all of the energy of the worst-case focal spot 5. Both of these solutions, however drive up system cost and complexity, and reduce efficiency.

A second problem with this prior art concentrating photovoltaic system 10 is that only one solar photovoltaic cell 4 is used for each condensing Fresnel lens 2. Utilizing tandem photovoltaic cells having a variety of stacked photovoltaic junction bandgaps can significantly improve photovoltaic conversion efficiency. These tandem photovoltaic cells are formed by growing two or three photovoltaic cells atop one another in a semiconductor foundry.

An example of a typical triple junction cell 6 is illustrated in FIG. 2. In this triple junction photovoltaic cell 6, the uppermost junction 7 converts the shortest wavelengths to electricity, the middle junction 8 converts a middle band of solar wavelengths to electricity, and the lowest junction 9 converts the longest wavelengths to electricity. This configuration does offer a significant improvement in conversion efficiency, as photovoltaic cell efficiencies on the order or 40% have been reported. Unfortunately, this triple junction photovoltaic cell 6 requires a large number of layers, only some of which are shown in FIG. 2. The addition of each layer dramatically increases device complexity, decreases fabrication yield, and drives up the overall cost of the device. Furthermore, the amount of generated current produced by a tandem photovoltaic cell is limited to the amount of photocurrent produced by the internal junction that is creating the least amount of photocurrent. This governing action can severely limit the amount of electricity produced by a multi junction photovoltaic cell.

### SUMMARY

A solar conversion apparatus includes two or more conversion cells and a reflector assembly. Each of the two or more solar conversion cells is responsive to a different one of at least a first band of wavelengths from solar radiation and a second band of wavelengths from the solar radiation. The reflector assembly comprises at least two integrated reflective sections. One of the at least two reflective sections is positioned to reflect and direct the first band of wavelengths towards one of the two or more solar conversion cells and another one of the at least two reflective sections is positioned to reflect and direct the second band of wavelengths towards another one of the two or more solar conversion cells. At least one of the two integrated reflective structures comprises a Fresnel microstructure.

A method of making a solar conversion apparatus includes providing two or more solar conversion cells where each of the two or more solar conversion cells is responsive to a different one of at least a first band of wavelengths from solar radiation and a second band of wavelengths from the solar radiation. At least one of the two reflective sections is positioned to reflect and direct the first band of wavelengths towards one of the two or more solar conversion cells and another one of the at least two reflective sections is positioned to reflect and direct the second band of wavelengths towards another one of the two or more solar conversion cells. At least one of the two integrated reflective structures comprises a Fresnel microstructure.

This technology provides a number of advantages including providing a more efficient, better performing, and economical solar conversion apparatus. This technology is able to avoid prior problems with large focal spot sizes and the use of a large and expensive, multi junction photovoltaic cell by utilizing a lower reflector assembly comprising one or more Fresnel reflectors arranged in a cascade configuration. Each of these Fresnel reflectors is reflective to a selected band of wavelengths and is transmissive to other wavelengths that are in turn reflected by lower Fresnel reflectors. Additionally, each Fresnel reflector includes a microstructure that reflects and brings to a focus onto a photovoltaic cell a selected band of wavelengths that the photovoltaic cell is most responsive to. The resulting solar conversion apparatus has a high concentration ratio, is lossless over the range of wavelengths emitted by the sun that have significant energy content, and effectively directs the concentrated solar energy to the appropriate single or multi junction photovoltaic cell. Furthermore, since the semiconductor junctions are not fabricated into the tandem PV-cell but instead are separated into separate PV-cells, a junction producing less photocurrent than the other junctions will not restrict the output of the other junctions.

### BRIEF DESCRIPTION OF THE DRAWINGS

FIG. 1 is a side-view of a prior art concentrating photovoltaic (CPV) conversion apparatus;

FIG. 2 is a cross-sectional view of a prior art, multi junction photovoltaic cell;

FIG. 3 is a side-view of an exemplary solar conversion apparatus with three photovoltaic cells;

FIG. 4 is a cross-sectional view of a condensing lens in the solar conversion apparatus illustrated in FIG. 3;

FIG. 5 is a side-view of a reflector assembly in the solar conversion apparatus illustrated in FIG. 3;

FIGS. 6A-6C are graphs showing exemplary spectral reflectivities of three reflective layers in a reflector assembly in the solar conversion apparatus illustrated in FIG. 3;

FIG. 7 is a table of photovoltaic cell types with their bandgaps and operating wavelength bands;

FIG. 8A is a spectral response curve for a GaInAs photovoltaic cell;

FIG. 8B is a spectral response curve for a GaInP photovoltaic cell;

FIG. 8C is a spectral response curve for a GaAs photovoltaic cell;

FIG. 8D is a spectral response curve for a Germanium photovoltaic cell;

FIG. 8E is a spectral response curve for a Silicon photovoltaic cell;

FIG. 8F is a spectral response curve for a GaInP/GaAs double-junction photovoltaic cell;

FIG. 8G is a spectral response curve for a GaAs/Ge double-junction photovoltaic cell;

FIG. 9 is a graph showing an air-mass 1.5 insolation in 20 nm wavelength bands which is the spectral irradiance incident on a typical solar collector pointing directly at the sun;

FIG. 10 is a graph showing the maximum theoretical efficiency of a photovoltaic converter as a function of the number of junctions, in a system utilizing a solar concentrator that concentrates the solar illumination by 50×;

FIGS. 11A-11F are cross-sectional views of a process for manufacturing a reflector assembly for the solar conversion apparatus shown in FIG. 3;

FIG. 12 is a side-view of another exemplary solar conversion apparatus;

FIG. 13 is a side-view of a reflector assembly used in the solar conversion apparatus illustrated in FIG. 12 and without a condenser lens;

FIG. 14 is a side-view of a multi-cell solar conversion apparatus utilizing condenser lenses and having a lateral cell configuration in accordance with another embodiment of the present invention;

FIG. 15 is a plan-view of a four-cell solar concentrator assembly utilizing condenser lenses and having a lateral cell configuration in accordance with another embodiment of the present invention;

FIG. 16 is a side-view of yet another exemplary solar conversion apparatus without a condenser lens;

FIG. 17 is a side-view of a reflector assembly used in the solar conversion apparatus shown in FIG. 16; and

FIG. 18 is a perspective view of a solar tracking system used with a solar conversion apparatus.

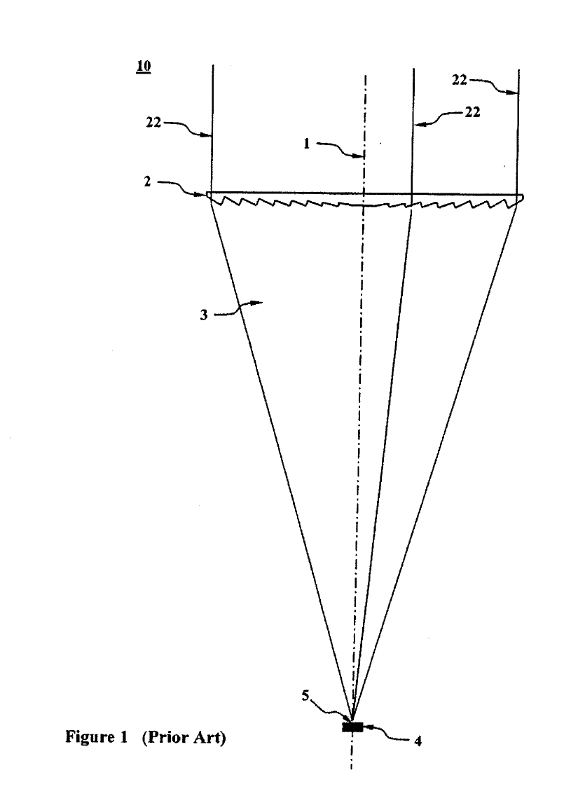

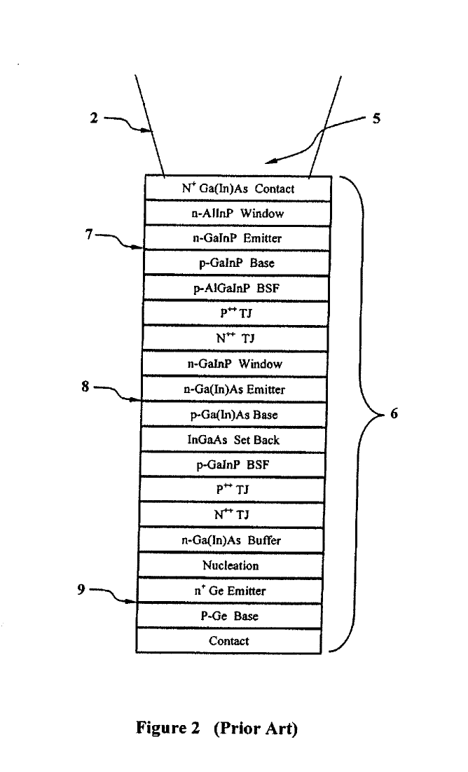

### DETAILED DESCRIPTION

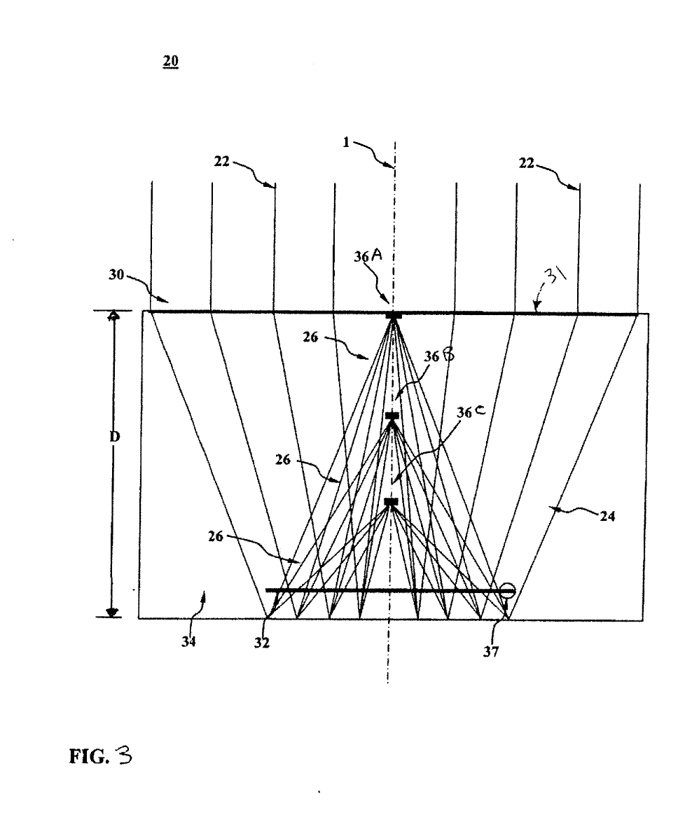

An exemplary solar conversion apparatus 20 is illustrated in FIG. 3. The solar conversion apparatus 20 includes a condensing lens 30, a reflector assembly 32, a rear bulkhead assembly 34, and photovoltaic cells 36A-36C, although the apparatus could comprise other numbers and types of systems, devices, components, cells and other elements in other configurations. The present invention provides a number of advantages including providing a more efficient, better performing, and economical solar conversion apparatus.

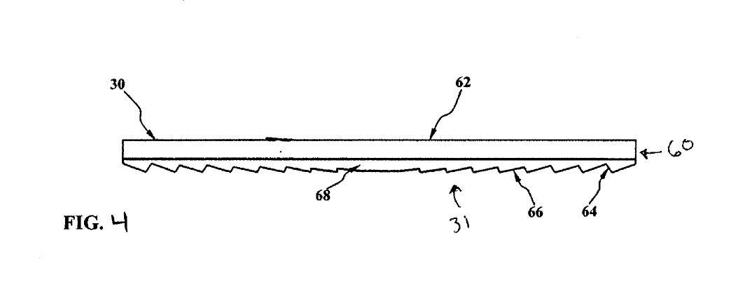

Referring more specifically to FIGS. 3-4, the condensing lens 30 is a plano-convex lens that is substantially transmissive to all wavelengths of light that the photovoltaic cells 36A through 36C are responsive to. In this example, this range is from about 350 nm to about 1900 nm which is the typical range of wavelengths of the sun. The plano side 31 is generally oriented in a direction towards the sun and can have a subwavelength microstructure 68 to reduce unwanted Fresnel reflection and thereby improve light transmittance, although this microstructure is optional and the side 31 also can have other types of surfaces and treatments, such as an antireflective (A/R) coating or no treatment at all. The subwavelength microstructure on the plano side 31 has the additional benefit of having self-cleaning properties owing to the so-called Lotus Effect.

Referring more specifically to FIG. 4, the condensing lens 30 is a Fresnel lens comprising two individual pieces, although the lens can have other constructions with other numbers of pieces, such as a monolithic unitary construction. If the condensing lens 30 has a monolithic unitary construction, it can be made from glass or a polymer material, such as acrylic, polycarbonate, or from silicone. In this example, the condensing lens 30 has a substrate 60 onto which is installed a layer of a Fresnel microstructure 68. The substrate 60 is made of glass which has excellent transmissivity, stability, ability to withstand decades of intense solar, especially ultraviolet (UV) radiation, and can also withstand environmental factors, such as extreme temperatures and hail, although the substrate can be made of other types of materials. By way of example only, the substrate 60 can also be made from a film material, such as PET, PEN, PC, or acrylic by way of example. The Fresnel microstructure 68 is made of silicone which is also highly transmissive to the range of solar wavelengths that the photovoltaic cells 36A-36C are responsive to, although the microstructure can be made other types of materials. By way of example only, the Fresnel microstructure 68 can be a UV curable resin installed in a roll-to-roll process.

The Fresnel microstructure 68 has a series of triangular grooves having slope surfaces 66 and draft surfaces 64. The slope surfaces 66 which perform the work of optically bending the incident solar energy 22 are designed so the focal length of the condensing lens 30 is approximately twice the cavity depth D (shown in FIG. 3) for the short wavelength band of solar radiation that photovoltaic cell 36A is responsive to (the focal length of the condensing lens 30 varies with wavelength because of the dispersion of the material comprising the Fresnel microstructure 68). In this example, the condensing lens 30 and the reflector assembly 32 comprise circularly symmetric optical elements, such as

Fresnel surfaces, whose optical axis is substantially collinear with the optical axis 1 of the concentrator.

Referring to FIG. 5, a magnified view of a small section 37 of the reflector assembly 32 shown in FIG. 3 is illustrated. The reflector assembly 32 comprises layers 201-206, although the assembly can have other types and numbers of layers. In this example, the lowermost layer 201 is a substrate layer substantially planar on each side and is made of a substantially rigid material such as glass, although it can be made in other manners, such as thin and flexible, and made of other materials, such as a sheet of polymer film. The next layer 202 has a Fresnel microstructure 50 and an adhesive-encapsulant 51 that are separated by a reflective layer 48C, although this layer could have other types and numbers of parts and layers. The next layer 203 also is substantially planar on each side and is made of a substantially rigid material such as glass, although it can be made in other manners, such as thin and flexible, and made of other materials, such as a sheet of polymer film. The next layer 204 has a Fresnel microstructure 53 and an adhesive-encapsulant 54 that are separated by a reflective filtering layer 48B, although this layer could have other types and numbers of parts and layers. The Fresnel microstructure 53 generally has a different optical prescription than Fresnel microstructure 50. The next layer 205 also is substantially planar on each side and is made of a substantially rigid material such as glass, although it can be made in other manners, such as thin and flexible, and made of other materials, such as a sheet of polymer film. The material of layer 205 also is substantially planar on each side and is made of a substantially rigid material such as glass, although it may be different than the material used in layers 201 and 203. Finally, the uppermost surface 206 of layer 205 has a reflective filtering layer 49 deposited onto it, although other types and numbers of layers could be deposited.

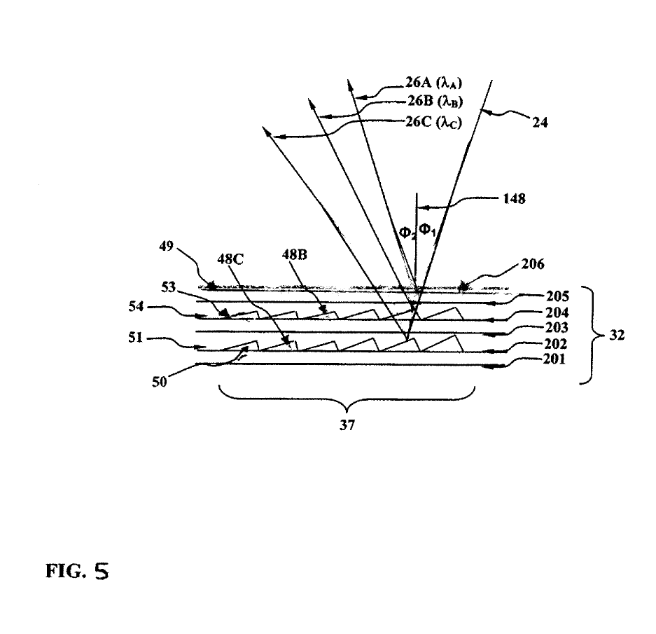

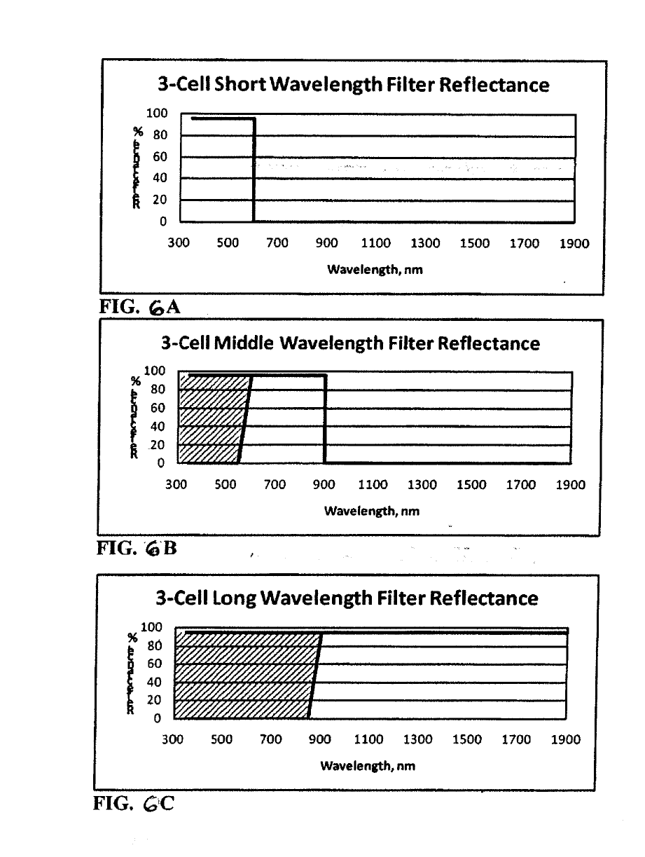

The layers 48C, 48B, and 49 will now be described with reference to FIGS. 6A-6C. The graphs shown in FIGS. 6A-6C plot the reflectivity of each of the layers 48C, 48B, and 49 over the range of wavelengths that are being concentrated. Each of the layers 48C, 48B, and 49 reflects a limited wavelength band, such that the light that is reflected is concentrated and focused onto one of the photovoltaic cells 36A-36C that is most sensitive to that band of wavelengths. The reflective filtering layer 49 has the reflectance illustrated in FIG. 6A, and reflects wavelengths less than 600 nm and transmits all others. Light reflected from the reflective filtering layer 49 can be concentrated onto a photovoltaic cell having spectral responsivity between 350 nm and 600 nm, such as InGaP.

In this example, light of a wavelength greater than 600 nm is transmitted through the reflective filtering layer 49 and is incident on the reflective filtering layer 48B that has the spectral reflectance as shown in FIG. 6B, although other wavelength ranges could be used. The reflective filtering layer 48B is transmissive to wavelengths greater than about 900 nm and is reflective to wavelengths between about 600 nm and about 900 nm. The reflective filtering layer 48B also is transmissive to light at wavelengths less than about 600 nm, although the reflective filtering layer 48B also could be reflective or even partially reflective as there is essentially no light reaching the reflective filtering layer 48B in these wavelengths as they are all being reflected by the reflective filtering layer 49. Additionally, other wavelength ranges could be used. Light reflected from the reflective filtering layer 48B in the band from about 600 nm to about 900 nm would be concentrated onto a photovoltaic cell having spectral responsivity between about 600 nm and about 900 nm, such as GaAs, although other wavelength ranges could be used.

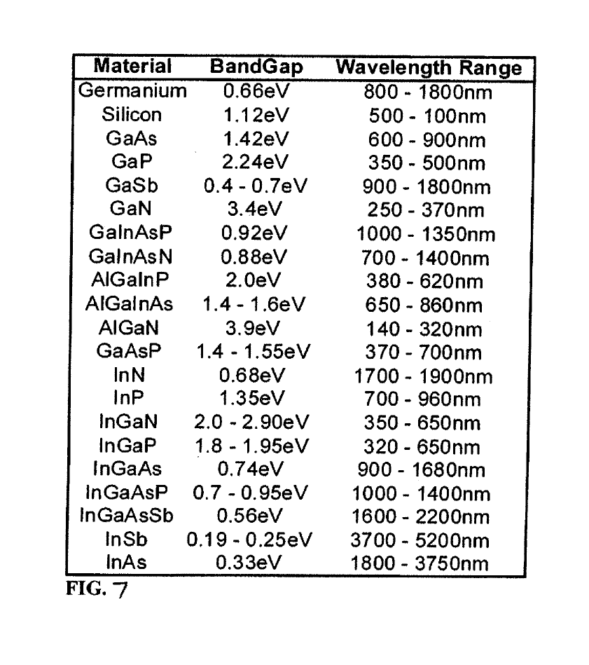

Light of a wavelength greater than about 900 nm is transmitted through the reflective filtering layer 49 and the reflective filtering layer 48B and is incident on the reflective layer 48C that has the spectral reflectance as shown in FIG. 6C although other wavelength ranges could be used. The reflective layer 48C is reflective to wavelengths greater than about 900 nm and is transmissive to light at wavelengths less than about 900 nm, although the reflective layer 48C also could be reflective or even partially reflective as there is essentially no light reaching the reflective layer 48C in these wavelengths as they are all being reflected by the reflective filtering layer 49 and the reflective filtering layer 48B. Additionally, other wavelength ranges could be used. Light reflected from the reflective layer 48C reflecting light in the band from about 900 nm to about 1800 nm could be concentrated onto a photovoltaic cell having spectral responsivity between about 900 nm and about 1800 nm, such as Germanium, although other wavelength ranges could be used. The reflectance wavelength bands shown in FIGS. 6A-6C are for illustration purposes only. The bands wavelengths may vary in accordance with the spectral characteristics of the photovoltaic cells used in the solar conversion apparatus 20. By way of example, a table of materials for photovoltaic cells with their respective bandgaps and operating wavelength bands which can be used is illustrated in FIG. 7.

Referring back to FIG. 5, the upper surface 206 of layer 205 is a substantially planar surface with no optical power and the reflective filtering layer 49 constitutes a flat mirror that is reflective to the band of wavelengths as described above in connection to FIG. 6A. If a line 148 is drawn perpendicular to the upper surface 206 of layer 205 at any arbitrary location on the plain of the reflective filtering layer 49, then an incoming white light ray 24 makes an angle of incidence Φ₁ with respect to the perpendicular line 148. This light ray 24 follows the law of reflection and reflects from the reflective filtering layer 49 at an angle Φ₂=Φ₁ into light ray 26A for the wavelengths that the reflective filtering layer 49 are reflective to.

The two reflective layers 48B and 48C are internal to the reflector assembly 32. The reflective filtering layer 48B is installed onto the Fresnel microstructure 53 resulting in a Fresnel mirror that is reflective only to the band of wavelengths as described above in connection to FIG. 6B. The reflective filtering layer 48B will cause incident light rays 24 having wavelengths that are transmitted through reflective filtering layer 49 to come to a focus on a photovoltaic cell 36B whose location on the optical axis 1 is determined by the focal length of the condensing lens 30 and the focal length of the reflecting microstructure 53 in layer 204.

The reflective layer 48C is installed onto the Fresnel microstructure 50 resulting in a Fresnel mirror that is reflective only to the band of wavelengths as described above in connection to FIG. 6C. The reflective layer 48C will cause incident light rays 24 having wavelengths that are transmitted through reflective filtering layer 49 and reflective filtering layer 48B to come to a focus on a photovoltaic cell 36C whose location on the optical axis 1 is determined by the focal length of the condensing lens 30 and the focal length of the reflecting microstructure 50 in layer 202. Accordingly, as illustrated and described herein, the reflector assembly 32 with the Fresnel microstructures 50 and 53 results in a solar conversion apparatus 20 with considerable performance and economic advantage over other solar conversion apparatuses using other types of reflective optics.

Referring back to FIG. 3, the solar conversion apparatus 20 includes the photovoltaic cells 36A-36C, although the apparatus could include other numbers and types of solar conversion cells. In this example, the photovoltaic cell 36A is responsive to short-wavelength solar light, such as in the range of from 350 nm to 650 nm, the photovoltaic cell 36B is responsive to an intermediate band of wavelengths such as in the range of from 650 nm to 900 nm, and the photovoltaic cell 36C is most responsive to long-wavelength solar energy, such as in the range from 900 nm to 1800 nm. All of the photovoltaic cells 36A-36C are located substantially on the optical axis 1 with the photovoltaic cell 36A located at or near the location of an condensing lens 30, although the photovoltaic cells could have other orientations, such as off axis.

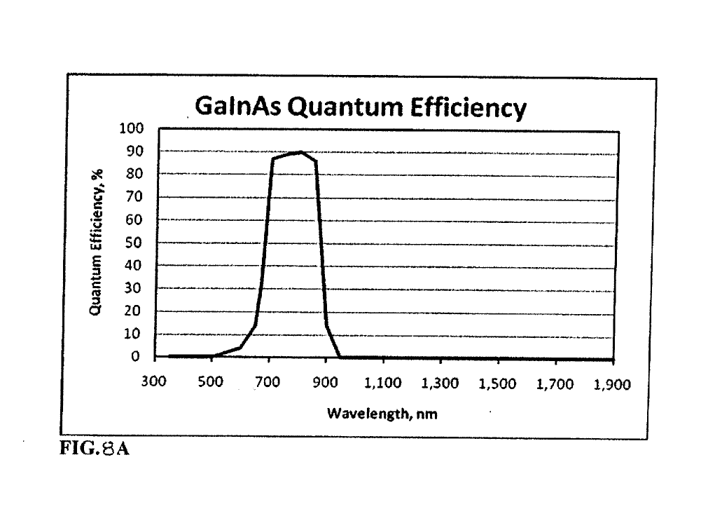

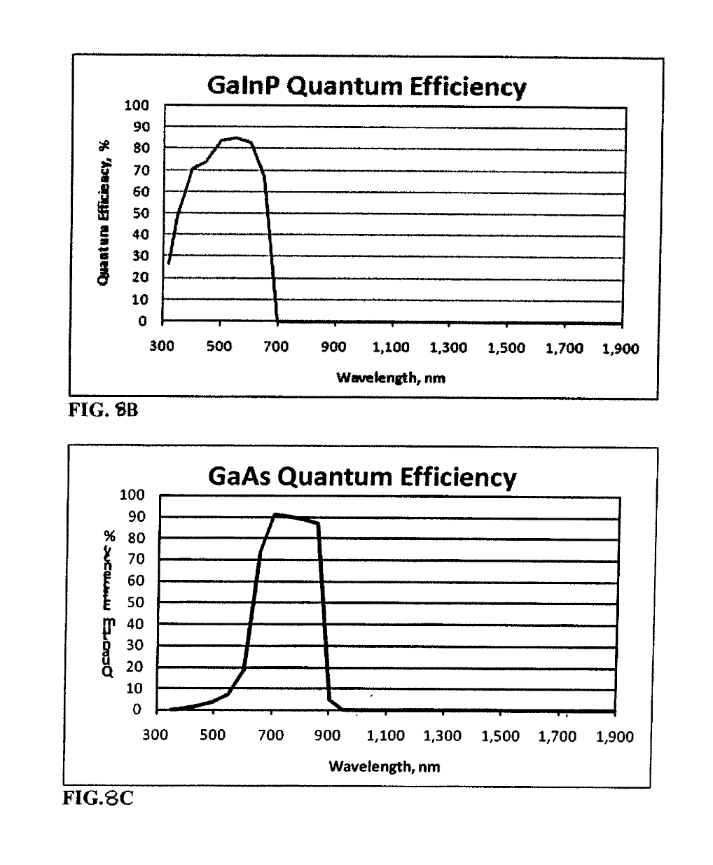

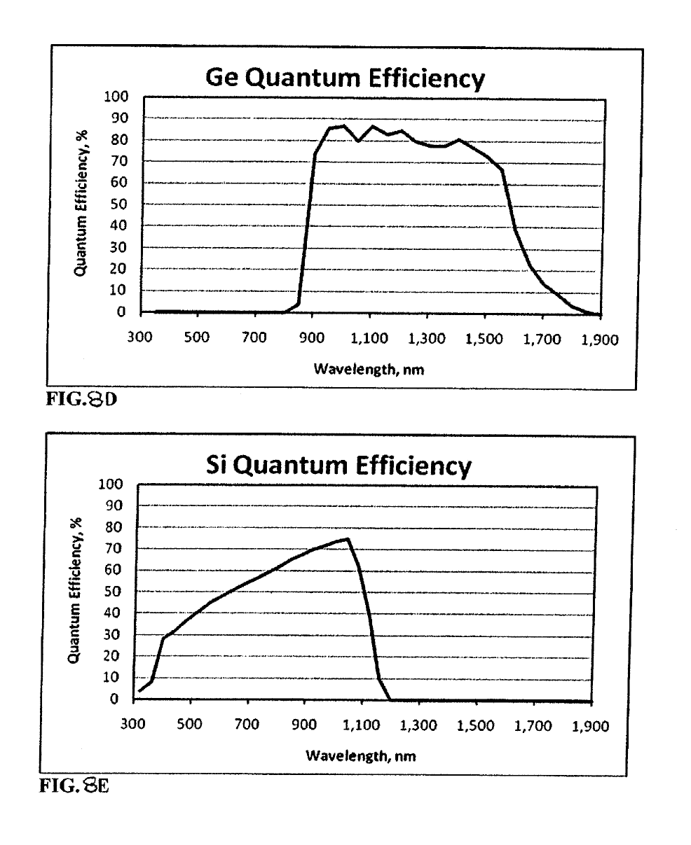

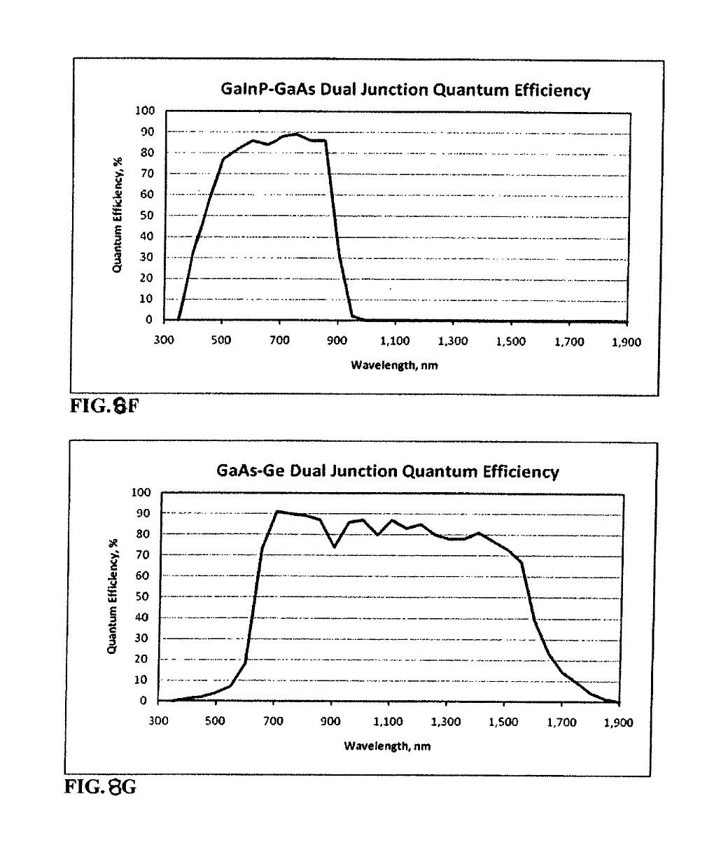

The photovoltaic cells 36A-36C can be made from a wide variety photovoltaic cell materials and alloys. By way of example only, graphs in FIG. 8A-8E show the responsivity of a few of single junction photovoltaic cells while FIGS. 8F and 8G show the responsivity of a couple of double junction photovoltaic cells. Additionally, the table illustrated in FIG. 7 provides an additional exemplary listing of materials that can comprise a single junction photovoltaic cell, their bandgap energies, and usable wavelength ranges. The photovoltaic cells 36A-36C are selected to, in sum, cover the usable wavelength ranges for solar energy from about 350 nm to about 1800 nm as illustrated in FIG. 9, although as explained in greater detail below other numbers of photovoltaic cells can be used.

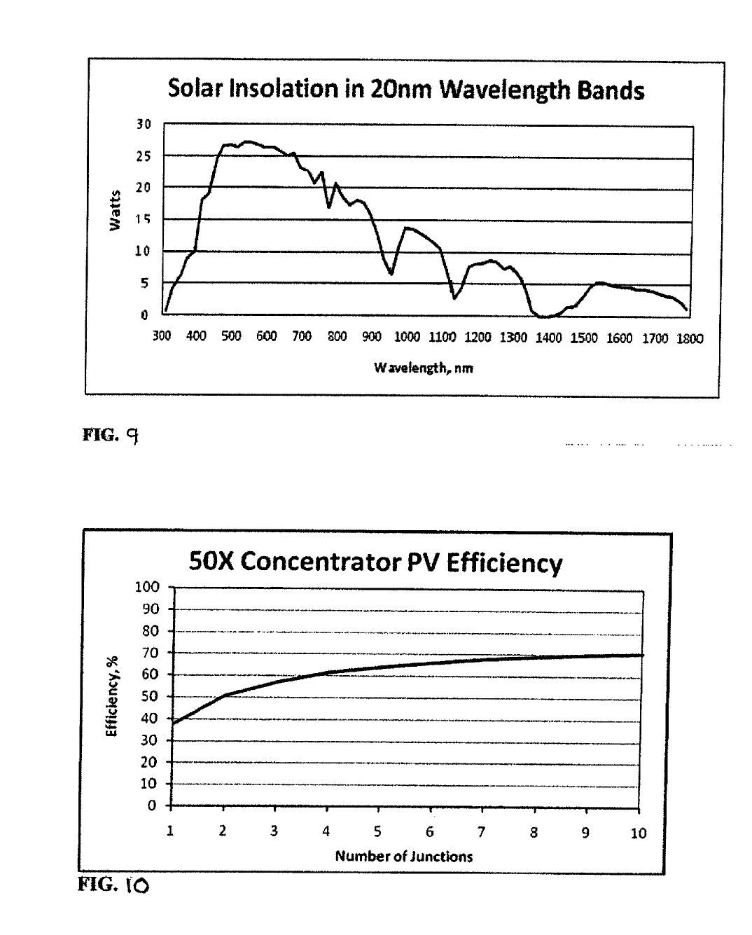

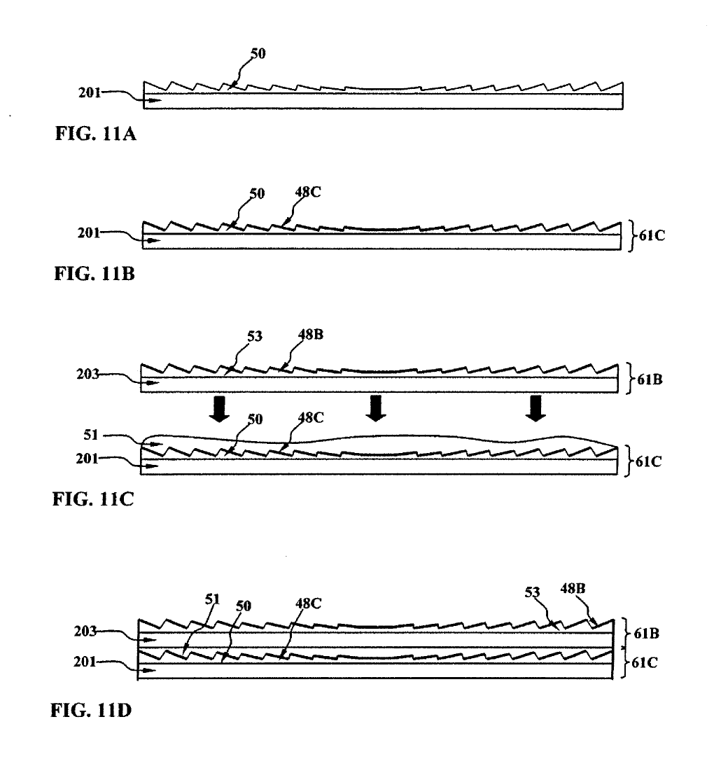

The solar apparatus conversion system 20 economically and efficiently separates the solar energy into three discrete wavelength groupings and directs each group of concentrated solar energy onto the particular photovoltaic cells 36A-36C that is optimal for the wavelengths that are directed to it. As illustrated in FIG. 10, as the number of discrete bands the solar conversion apparatus 20 separates the solar energy into increases, the conversion efficiency increases. By way of example only, a solar conversion apparatus which separates the solar energy into four bands for capture by four correspondingly selected photovoltaic cells could achieve about 60% efficiency while a solar conversion apparatus which separates the solar energy into ten bands could achieve nearly 70% conversion efficiency at a 50× concentration ratio.

Referring back to FIG. 3, the solar conversion apparatus 20 also comprises the rear bulkhead surface 34. The reflector assembly 32 is located on the rear bulkhead assembly 34. A mechanical mounting assembly retains the position of these photovoltaic cells 36A, 36B, and 36C along an optical axis 1 between the condensing lens 30 and the reflector assembly 32, although other manners for securing the position of the photovoltaic cells, condensing lens, and reflector assembly and in other configurations can be used.

The operation of the solar conversion apparatus 20 will now be described with reference to FIGS. 3-5. The solar conversion apparatus 20 is exposed to solar radiation 22 that is being concentrated. This solar radiation 22 is polychromatic and for purposes of this discussion comprises three individual rays of solar radiation 22 having wavelength groups λ_{A}, λ_{B}, and λ_{C}, that represent typical wavelength ranges that photovoltaic cells 36A, 36B, and 36C, respectively, are responsive to and are reflected by reflective layers 49, 48B, and 48C respectively. Wavelength groupings λ_{A}, λ_{B}, and λ_{C} are generally non-overlapping yet together substantially span the solar radiation spectra as shown in FIG. 9. In this example, wavelength group λ_{A} includes wavelengths between about 300 nm and about 600 nm, λ_{B} includes wavelengths between about 600 nm and about 900 nm, and λ_{C} includes wavelengths between about 900 nm and about 1800 nm.

The condensing lens 30 causes any of the incident solar radiation 22 to converge. These converging rays, such as converging white light ray 24 (which contains all wavelengths of groupings λ_{A}, λ_{B}, and λ_{C}), are incident on the reflective filtering layer 49 of the reflector assembly 32. Due to the reflectance characteristics of the reflective filtering layer 49, light rays 26A of wavelength group λ_{A} are reflected in accordance with the Law of Reflection, and all other wavelength groups (λ_{B} and λ_{C}) are transmitted into the reflector assembly 32 in accordance with Snells Law. The prescription of the condensing lens 30 is such that the light rays 26A of wavelength group λ_{A} are brought to a focus on the photovoltaic cell 36A. If the location of the photovoltaic cell 36A is such that it is coplanar with the condensing lens 30, then the focal length of the condensing lens 30 must be approximately twice the distance between condensing lens 30 and the reflective filtering layer 49, which is 2×D. The photovoltaic cell 36A is selected to be highly responsive to wavelength group λ_{A} of incident rays 26A and converts the incident solar energy of these rays into electricity with very high efficiency.

After passing through reflective filtering layer 49 and refracting into the reflector assembly 32, wavelength group λ_{B} propagates through layer 205 and into layer 204 where it becomes incident on reflective filtering layer 48B. Reflective filtering layer 48B is installed onto the Fresnel microstructure 53 and therefore cooperatively forms a Fresnel mirror. Additionally, reflective filtering layer 48B in accordance with its spectral reflectance profile shown in FIG. 6B is reflective to wavelength group λ_{B}. Therefore, as shown in the close-up view in FIG. 5, the light rays 26B of wavelength group λ_{B} reflect off the slope surfaces of the Fresnel microstructure 53 within layer 204. Furthermore, the Fresnel mirror within layer 204 has optical power to wavelength group groupings λ_{B} such that the output angle θ₂ is not equal to the input angle θ₁ at the upper surface 206 of the reflector assembly 32. This means that the focal position of the exiting light rays 26B having wavelength group λ_{B} will not be at the location of the photovoltaic cell 36A, but instead are brought to a focus on photovoltaic cell 36B with little or no interference with the operation of photovoltaic cell 36A. The photovoltaic cell 36B is selected to be highly responsive to wavelength group λ_{B} of incident rays 26B and converts the incident solar energy of these rays into electricity with very high efficiency.

After passing through reflective filtering layer 49 and refracting into the reflector assembly 32, wavelength group λ_{C} propagates through layers 205, 204, 203 and into layer 202 whereupon it becomes incident on reflective layer 48C. Reflective filtering layer 48B is not reflective to wavelength group λ_{C} and these rays pass through reflective filtering layer 48B substantially undeviated in direction. Additionally, the reflective layer 48C is installed onto the Fresnel microstructure 50 and therefore cooperatively forms a Fresnel mirror. The reflective layer 48C in accordance with its spectral reflectance profile shown in FIG. 6C is reflective to wavelength group λ_{C}. Therefore, as shown in the close-up view in FIG. 5, the light rays 26C of wavelength group λ_{C} reflect off the slope surfaces of the Fresnel microstructure 50 within layer 202. Furthermore, the Fresnel mirror within layer 202 has optical power to light rays 26C comprising wavelength group λ_{C} such that the output angle θ₂ is not equal to the input angle θ₁ at the surface 206 of the reflector assembly 32. Furthermore, light rays 26C exit the reflector assembly 32 at a more aggressive converging rate (i.e., faster f/#) than the other two light ray groupings λ_{A} and λ_{B}. This means that the focal position of the exiting rays 26C having wavelength group λ_{C} will not be at the location of the photovoltaic cell 36A or the photovoltaic cell 36B, but instead are brought to a focus on photovoltaic cell 36C with little or no interference with the operation of photovoltaic cell 36A or photovoltaic cell 36B. The photovoltaic cell 36C is selected to be highly responsive to wavelength group λ_{C} of light ray 26C and converts the solar energy of these rays into electricity with very high efficiency.

Accordingly, as illustrated and described herein, the solar conversion apparatus 20 offers a considerable performance and economic advantage over prior art single junction solar concentrators and triple junction tandem photovoltaic cells. Additionally, although the solar conversion apparatus 20 is illustrated with three photovoltaic cells 36A-36C, the solar conversion apparatus can have additional photovoltaic cells with improved conversion efficiency as illustrated in FIG. 10.

An exemplary method for constructing the condensing Fresnel lens 30 will now be described with reference to FIG. 4. A sheet, plate, or film of material that is substantially flat on both its upper and lower sides is provided that serves as the substrate 60 for the condensing Fresnel lens 30. This substrate is made from glass and ranges from about 0.1 mm to about 10 mm thick, although other types of materials, such as a polymer, and other thicknesses can be used. Since the condensing Fresnel lens 30 needs to be self-supporting and able to withstand a variety of environmental stresses, the substrate 60 is generally made from glass that is between about 2 mm and about 5 mm thick. The input side 62 of the substrate 60 is treated with an A/R coating to reduce unwanted Fresnel reflections at the input surface 62, although other manners for reducing reflections can be used, such as a subwavelength microstructure formed on the input side 62 of the substrate 60.

A Fresnel microstructure 68 is installed on the lower side of the condensing Fresnel lens 30. The microstructure 68 comprises a polymer material, such as a UV-cured resin, although other types of materials can be used, such as silicone which has transmittance over the entire 350 nm to 18900 nm solar insolation range and it is relatively immune to UV damage from the solar UV light. The prescription of the slope surfaces 66 of the Fresnel microstructure is formed so that it results in a focal length of the condensing Fresnel 30 of 2D for the shorter wavelength band (i.e., λ_{A}). Longer wavelengths will generally see a longer focal length because the refractive index of the material comprising the microstructure 68 is lower at the longer wavelengths because of the materials dispersion.

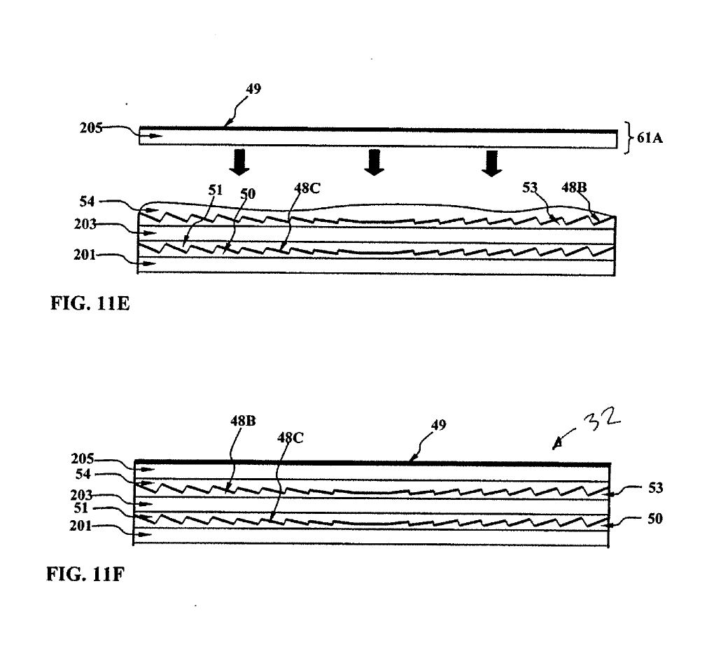

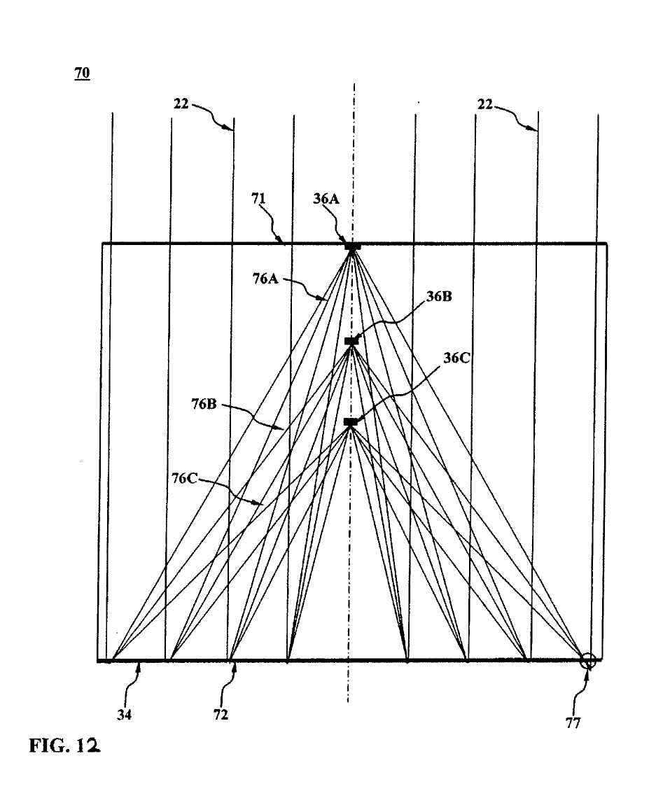

An exemplary method for constructing and assembling the reflector assembly 32 will now be described with reference to FIG. 11A-11F. In this example, the Fresnel microstructure 50 is formed on a substrate layer 201 resulting in the object shown in FIG. 11A. The microstructure 50 is a UV-cured resin, although the microstructure can be made of other types of materials, such as a silicone material. Additionally, the substrate layer 201 is glass, although the layer can be made of other types of materials, such as a polymer. The microstructure 50 is installed onto the layer 201 in a cell-cast or other type of casting process, although other methods can be used. For example, layer 201 and microstructure 50 can be formed as a unitary object using a molding process, such as injection molding, compression molding, or injection-compression molding.

Next, a specularly-reflecting reflective coating layer 48C is applied to the slope surfaces of the microstructure 50, resulting in the lower reflecting Fresnel 61C shown in FIG. 11B. The reflective coating layer 48C can be applied to the draft surfaces of the microstructure 48C, but this is of little consequence because the draft surfaces are substantially unused in the system, and it is preferred that the draft surfaces are left uncoated. The reflecting layer 48C is metallic, such as gold, silver, or aluminum by way of example only, or an interference stack of thin films that reflects the desired band of wavelengths, in this example for solar conversion apparatus 20 the wavelengths band λ_{C}.

In addition to the lower reflecting Fresnel 61C, a reflective filtering Fresnel 61B also is prepared in a process similar or identical to the process described above for the lower reflecting Fresnel 61C. After both the lower reflecting Fresnel 61C and the middle reflective filtering Fresnel 61B are available, they must be bonded together. As shown in FIG. 11C, a layer of encapsulant adhesive 51 in a liquid form and that can act as an adhesive when hardened is applied atop the coated microstructure 50 and reflecting layer 48C. The rear surface of the reflective filtering Fresnel 61B is then brought into contact with the encapsulant adhesive 51, and gently compressed to squeeze out any excess encapsulant adhesive 51.

The encapsulant adhesive 51 is allowed to cure, dry, or otherwise harden resulting in the assembly depicted in FIG. 11D. The encapsulant adhesive 51 is an adhesive and is the same material that is used to form the Fresnel microstructure 50 so that the properties of the material are the same on both sides of the reflecting layer 48C, although other types of adhesives and materials can be used. This will ensure that light rays that are transmitted through the reflecting layer 48C do not bend or otherwise refract as they cross the interface between the encapsulant adhesive layer 51 and the microstructure 50 because it ensures that the refractive indices of the two materials are the same for all transmitted wavelengths.

Next, the reflector assembly portion 61A comprising a substrate layer 205 and reflective filtering layer 49 are prepared. Both the upper and lower sides of the substrate upper layer 205 are planar and the substrate upper layer 205 is made from polymer, although other types of materials can be used, such as glass. The reflective filtering layer 49 is an interference stack of thin films that reflects the desired band of wavelengths (i.e., λ_{A}). After both reflecting Fresnel assembly portions 61C and 61B and reflector assembly portion 61A are available, they must be bonded together. As shown in FIG. 11E, a layer of transparent material 54 in a liquid form and that can act as an adhesive when hardened is applied atop the coated microstructure 53 and reflective filtering layer 48B. The rear surface of the upper reflector assembly portion 61A is then brought into contact with the transparent encapsulant adhesive 54 and gently compressed to squeeze out any excess encapsulant adhesive 54, although other manners for joining the portions with other adhesives can be used.

The transparent encapsulant adhesive 54 is then allowed to cure, dry, or otherwise harden, resulting in the reflector assembly 32 depicted in FIG. 11F. The transparent encapsulant adhesive 54 is an adhesive and is the same material that is used to form the Fresnel microstructure 53 so that the properties of the material are the same on both sides of the reflective filtering layer 48B, although other types of adhesives and materials can be used. It is important that the optical properties of the materials be the same on both sides of the reflective filtering layer 48B because if they are not the same, for example if they have different refractive indices or dispersion, then the difference in refractive index will cause refraction to occur as light rays (i.e., of wavelength band 4) pass through the reflective filtering layer 48B. That is the microstructure 53 will then have optical power and act as a lens and the light rays will not pass through the interface at the reflective and filtering layer 48B unchanged in direction. This will compromise the optical concentration performance of the solar conversion apparatus 20.

In other examples, the solar conversion apparatus assembly process can be streamlined if, instead of having two optically active devices (the condensing lens 30 and the reflector assembly 32), there were only one. This can be accomplished by dispensing with the condensing lens 30 and by installing an additional reflecting Fresnel mirror within the reflector assembly.

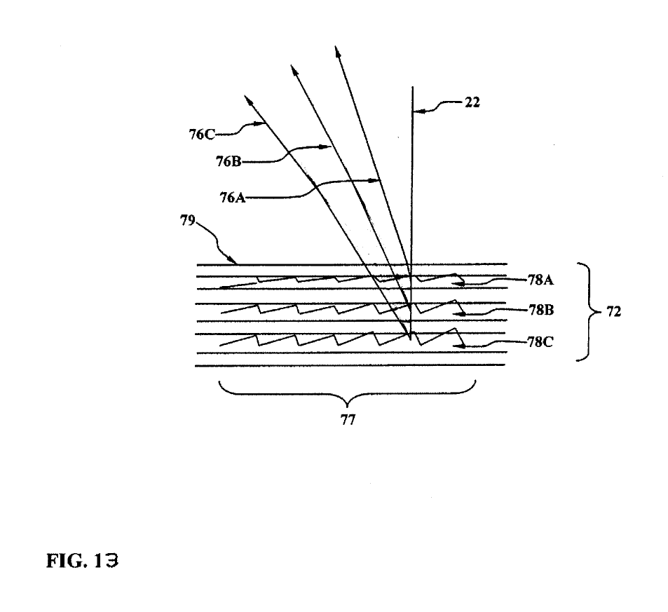

Referring to FIGS. 12-13, another exemplary solar conversion apparatus 70 with this streamlined configuration is illustrated. The solar conversion apparatus 70 illustrated in FIGS. 12-13 is the same in structure and operation as the solar conversion apparatus 20 shown in FIGS. 3-5 except as described and illustrated herein. In the solar conversion apparatus 70, the condensing lens 30 is replaced with a flat plate 71 that is substantially transparent to all wavelengths that the photovoltaic cells 36A, 36B, and 36C are responsive to. Solar radiation 22 passes through the flat plate 71 substantially unchanged in direction, and travel all the way through the concentrator 70 to the reflector assembly 72.

Referring more specifically to FIG. 13, an enlarged view of a small section 77 of the reflector assembly 72 is shown. The reflector assembly 72 is the same in structure and operation as the reflector assembly 32, except as illustrated and described herein. In the reflector assembly 72, the reflective filtering layer 49 has been eliminated from reflector assembly 72 and optionally replaced with an A/R treatment at the upper surface 79 of the reflector assembly 72. Additionally, instead of the reflector assembly 72 having two internal Fresnel mirrors as shown with the reflector assembly 32, there are three Fresnel mirrors 78A, 78B, and 78C. The three Fresnel mirrors 78A-78C each have different optical power and are coated with different reflecting filters to reflect specific bands of wavelengths as previously described in the corresponding embodiment of the solar conversion apparatus 20.

In operation Fresnel mirror 78A reflects and focuses its band of wavelengths (e.g., λ_{A}) onto photovoltaic cell 36A and transmits all others (e.g., λ_{B} and λ_{C}) substantially undeviated. Fresnel mirror 78B reflects and focuses its band of wavelengths (e.g., λ_{B}). onto photovoltaic cell 36B and transmits all others (e.g., λ_{C}) substantially undeviated. Fresnel mirror 78C reflects and focuses all remaining wavelengths (e.g., λ_{C}) onto photovoltaic cell 36C. With this configuration for the solar conversion apparatus 70, the size of the reflector assembly 72 must be increased to fill the entire rear bulkhead surface 34 due to the absence of a condensing lens 30.

One problem that is common to the embodiments described thus far has to do with the placement of the photovoltaic cells 36A-36C on the optical axis 1. This gives rise to the shadow-loss problem wherein a portion of the light that would be incident on an upper photovoltaic cell, such as photovoltaic cell 36A is blocked by a lower photovoltaic cell such as photovoltaic cell 36B. In other words photovoltaic cell 36A is partly shadowed by lower photovoltaic cell 36B. Accordingly, to overcome the shadow losses it is necessary to install the photovoltaic cells in an off-axis location outside the cone of converging rays.

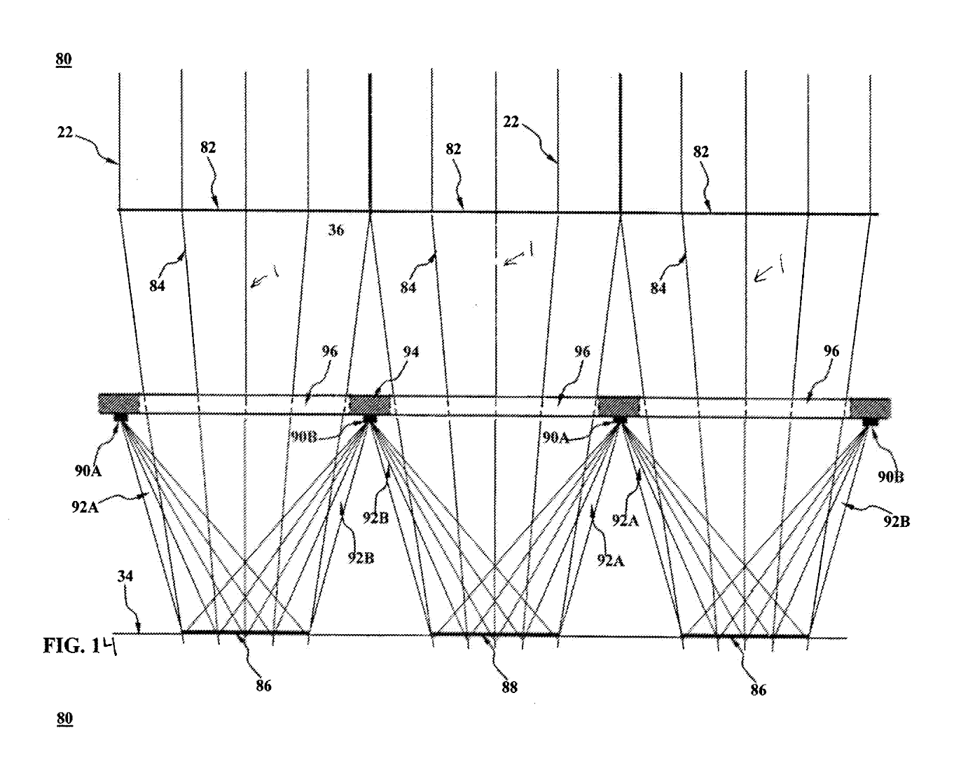

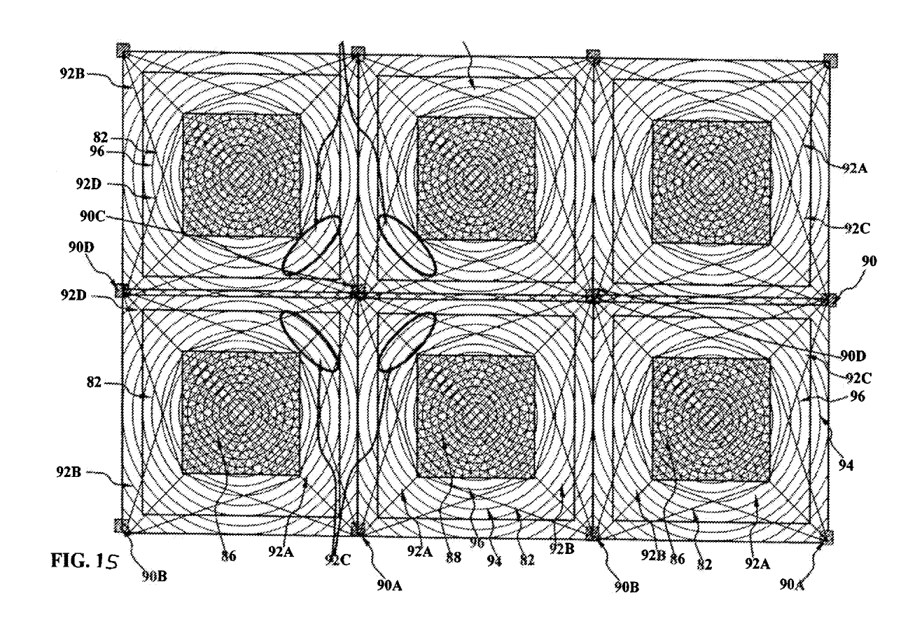

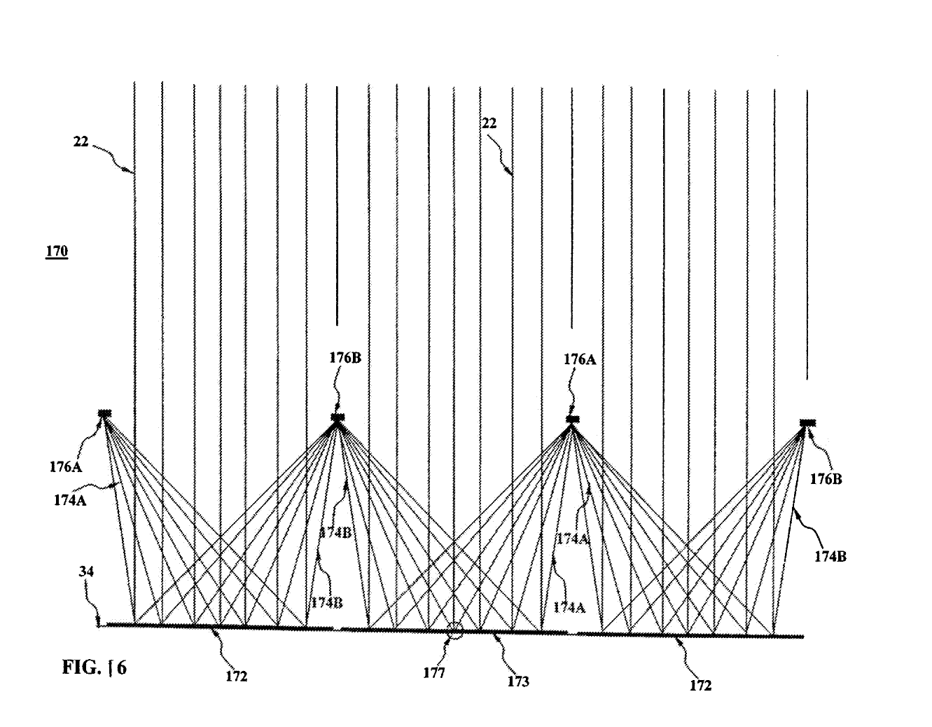

The side-view of one such off-axis solar conversion apparatus 80 is shown in FIG. 14 and a plan view of this apparatus 80 is shown in FIG. 15. The solar conversion apparatus 80 is the same as the solar conversion apparatus 20, except as described and illustrated herein. This solar conversion apparatus 80 comprises a condensing lens 82, an internal bulkhead 94 having apertures 96, four reflector assemblies 86, 87, 88, and 89 mounted onto a rear bulkhead 34, and four different types of photovoltaic cells, 90A, 90B, 90C, and 90D.

The reflector assemblies 86-89 each comprise four reflective filtering Fresnels installed as described earlier that split and reflect the incident converging solar energy 84 into four groups of light 92A, 92B, 92C, and 92D (each containing only a limited band of wavelengths) and focus the four groups of light 92A-92D onto the four different photovoltaic cells 90A-90D, respectively that are most responsive to the wavelengths of light incident directed onto them.

The four different types of photovoltaic cells 90A, 90B, 90C, and 90D are mounted on the internal bulkhead 94. Additionally, the four photovoltaic cells 90A, 90B, 90C, and 90D are located away from the optical axis 1 and between the converging rays 84 so that there are no shadowing effects that reduce system efficiency. The four different types of photovoltaic cells 90A, 90B, 90C, and 90D and are selected to be responsive to four different wavelength bands of light spread across the solar energy spectrum from about 350 nm to about 1800 nm, although other numbers of photovoltaic cells responsive to other bands of wavelengths can be used. As illustrated in FIG. 10, increasing the number of bands and photovoltaic cells in the solar conversion apparatus 80 will increase performance and efficiency. Accordingly, the solar conversion apparatus 80 can be constructed with other numbers of photovoltaic cells and reflector assemblies, such as six of each to increase performance and efficiency, but with greater manufacturing complexity.

With this solar conversion apparatus 80, the photovoltaic cells 90A, 90B, 90C, and 90D are located where the corners of several concentrators meet so one photovoltaic cell can collect light of its wavelength band from four different concentrators. As a result, the number of photovoltaic cells in solar conversion apparatus 80 has been reduced by 75%. This is particularly evident in the plan view shown in FIG. 15, where by way of example photovoltaic cell 90C (on the middle-left) receives four groups of light 92C that it is responsive to from four different concentrators (having reflector assemblies 87, 89, 88, and 86).

In operation, the solar conversion apparatus 80 accepts solar radiation 22 that is incident on the condensing lens 82 which condenses the solar radiation into converging cones of light 84. The converging cones of light pass through apertures 96 in the internal bulkhead 94 and critically illuminates the reflector assemblies 86, 87, 88, and 89. The reflector assemblies 86, 87, 88, and 89 each comprise a different Fresnel microstructure which is used to reflect light towards the corresponding one of the photovoltaic cells 90A, 90B, 90C, and 90D responsive to the reflected band of wavelengths of the solar energy.

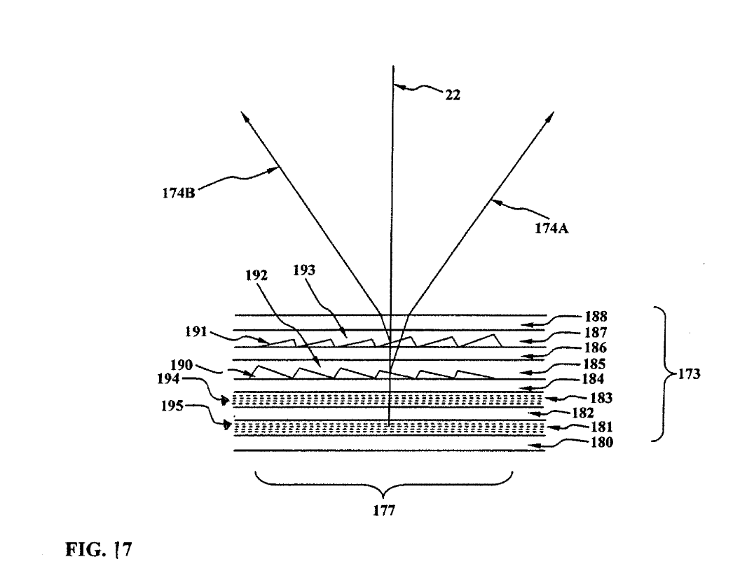

Referring to FIG. 16, another embodiment of a solar conversion apparatus 170 is illustrated. The solar conversion apparatus 170 is the same as solar conversion apparatus 80, except as illustrated and described herein. The solar conversion apparatus 170 also uses four photovoltaic cells arranged in the same lateral configuration as taught with solar conversion apparatus 80, however solar conversion apparatus 170 does not use an upper condensing Fresnel lens. Instead, solar radiation 22 is directly incident on the reflector assemblies 172 and 173 that separates the incident solar radiation into four distinct groups 174A and 174B (groups 174C and 174D are not shown) by their wavelengths, and focus these groups 174A and 174B onto their respective photovoltaic cells 176A and 176B. The photovoltaic cells 176A and 176B are matched to the bands of wavelengths (i.e., the photovoltaic cells have high responsivity to the wavelengths contained in the incident light) of the light groups 174A and 174B, respectively, that are focused onto them so the light is converted to electricity by the photovoltaic cells 176A and 176B with high efficiency. The four photovoltaic cells can be located at each of the four corners of the solar concentrator 170 in the same manner as illustrated with solar conversion apparatus 80, although other configurations could be used, such as along one or more sides. If several concentrators 170 are arranged in an array, placing the photovoltaic cells at the corners of the concentrators allow for the photovoltaic cells to be shared amongst the concentrators, thereby allowing for a reduction in the total number of photovoltaic cells as previously illustrated and described with reference to FIGS. 14-15.

Eliminating the upper condensing Fresnel lens from the solar conversion apparatus offers several advantages, including: 1) the cost of the condensing lens is eliminated; 2) the Fresnel reflection losses at the input and output surfaces are eliminated thereby increasing efficiency, and 3) the molds for the reflecting mirrors of the microstructure of the reflector assembly 173 are circularly symmetric and easier to tool and fabricate, thereby reducing the costs associated with the reflector assembly as compared to the solar conversion apparatus 80 shown in FIGS. 14 and 15.

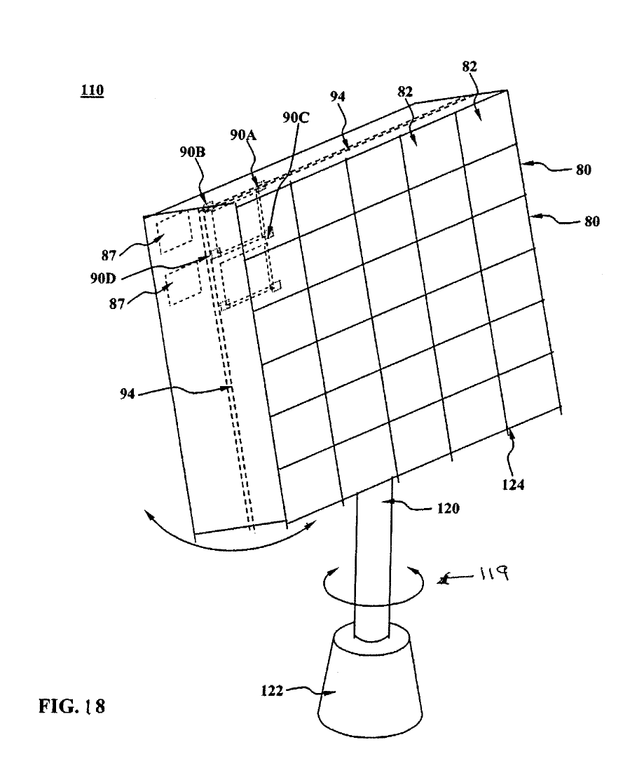

A magnified view of a small section 177 of reflector assembly 173 is shown in FIG. 17. As seen in the magnified view of the small section 177, the reflector assembly is made up of four Fresnel mirrors comprising microstructures 191, 190, 194, and 195 in layers 187, 185, 183, and 181, respectively. Layers 188, 186, 184, 182, and 180 are substrate layers made of glass, although other types of materials that support and add rigidity to the microstructure layers, such as a polymer can be used. As in other embodiments, the slope surfaces of the microstructures 191, 190, 194, and 195 are coated with reflectors, such as an interference stack, such that the slopes are reflective to the band of wavelengths that their corresponding photovoltaic cell is most responsive to and that their respective slope surfaces are directing the light onto.

The encapsulating adhesive layers 192 and 193 are used to secure the layers in the same manner as described with earlier examples. The microstructures 194 and 195 in layers 183 and 181 go from side-to-side in this view, and are represented by dashed lines. The encapsulating adhesive, while also present in layers 181 and 183, are not explicitly shown from this view.

While four Fresnel mirrors and four types of photovoltaic cells are described as being used in solar conversion apparatus 170, a lower number, such as one, two, or three, can be used, or a higher number, such as six, can be used. Additionally, the photovoltaic cells can be single junction cells or multi junction type photovoltaic cells.

The operation of the solar conversion apparatus 170 is the same as the operation of the solar conversion apparatus 80, except that with the solar conversion apparatus 170 there is no condensing lens that accepts and condenses the solar radiation into converging cones of light. Instead, the solar radiation passes directly through to the microstructures 191, 190, 194, and 195 in layers 187, 185, 183, and 181 and is correspondingly reflected in bands to the laterally arranged photovoltaic cells with the appropriate responsivity to the reflected band of wavelengths.

Referring to FIG. 18, each of the solar conversion apparatuses also can be mounted on to a heliostat 119 to keep each of the solar conversion apparatuses pointing at the sun, although other manners for managing the positioning of the solar conversion apparatuses can be used. This particular example illustrates the solar conversion apparatus 80 mounted on the heliostat 119 with the general location of the internal bulkhead 94, the reflector assemblies 87, the condensing Fresnels 82, and the various photovoltaic cells 90A, 90C, and 90D also illustrated. The heliostat 119 comprises a base 122 which includes a motor (not shown) for rotating a post 120 connected between the base 122 and the solar conversion apparatus 80. The heliostat 119 also includes a second motor (not shown) that is attached to the post 120 and the array 124, and allows for tip-tilt pointing of the solar conversion apparatus 80. The rotational and tip-tilt angular control of the heliostat meets all the angular positioning requirements of the array 124 of concentrators 80.

Accordingly, as illustrated and described herein this technology provides a number of advantages, including providing a more efficient, better performing, and economical solar conversion apparatus. This technology is able to avoid prior problems with large focal spot sizes and the use of a large and expensive, multi junction photovoltaic cell by utilizing a lower reflector assembly comprising one or more Fresnel reflectors arranged in a cascade configuration. Each of these Fresnel reflectors is reflective to a selected band of wavelengths and is transmissive to other wavelengths that are in turn reflected by lower Fresnel reflectors. Additionally, each Fresnel reflector includes a microstructure that reflects and brings to a focus onto a photovoltaic cell a selected band of wavelengths that the photovoltaic cell is most responsive to. The resulting solar conversion apparatus has a high concentration ratio, is lossless over the range of wavelengths emitted by the sun that have significant energy content, and effectively directs the concentrated solar energy to the appropriate single or multi junction photovoltaic cell.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Further, the recited order of elements, steps or sequences, or the use of numbers, letters, or other designations therefore, is not intended to limit the claimed processes to any order except as may be explicitly specified in the claims. Accordingly, the invention is limited only by the following claims and equivalents thereto.

What is claimed is:

1. A solar conversion apparatus comprising:
two or more solar conversion cells, each of the two or more solar conversion cells is responsive to a different one of at least a first band of wavelengths from solar radiation and a second band of wavelengths from the solar radiation; and
a reflector assembly comprising at least two integrated reflective sections, one of the at least two reflective sections is positioned to reflect and direct the first band of wavelengths towards one of the two or more solar conversion cells and another one of the at least two reflective sections is positioned to reflect and direct the second band of wavelengths towards another one of the two or more solar conversion cells and at least one of the two integrated reflective structures comprises a Fresnel microstructure.

2. The apparatus as set forth in claim 1 wherein the two or more solar conversion cells are physically separated from each other.

3. The apparatus as set forth in claim 1 wherein the two or more solar conversion cells are substantially aligned along an optical axis which extends through the reflector assembly.

4. The apparatus as set forth in claim 1 wherein the two or more solar conversion cells are offset from an optical axis which extends through the reflector assembly.

5. The apparatus as set forth in claim 4 wherein the two or more solar conversion cells are each substantially positioned along a plane through which the optical axis intersects.

6. The apparatus as set forth in claim 4 wherein the two or more solar conversion cells further comprise at least four of the solar conversion cells which are each responsive to a different one of at least the first band of wavelengths from solar radiation, the second band of wavelengths from the solar radiation, a third band of wavelengths from the solar radiation, and a fourth band of wavelengths from the solar radiation.

7. The apparatus as set forth in claim 1 wherein at least one of the two or more solar conversion cells comprises a single junction photovoltaic cell.

8. The apparatus as set forth in claim 1 further comprising at least one mounting assembly that supports the two or more solar conversion cells with respect to the reflector assembly.

9. The apparatus as set forth in claim 1 wherein the one of the at least two reflective sections that is at least partially reflective to the first band of wavelengths is substantially transmissive to at least the second band of wavelengths.

10. The apparatus as set forth in claim 9 wherein the at least one of the reflective sections with the Fresnel microstructure further comprises an internal reflector on a surface of the Fresnel microstructure, the internal reflector is at least partially reflective to one of the first band of wavelengths and the second band of wavelengths, the Fresnel microstructure is optically configured to direct the one of the first band of wavelengths and the second band of wavelengths at least partially reflected by the internal reflector towards one of the two or more solar conversion cells.

11. The apparatus as set forth in claim 10 wherein the internal reflector is at least partially transmissive to at least the other one of the first band of wavelengths and the second band of wavelengths.

12. The apparatus as set forth in claim 9 wherein the reflective system further comprises:
a first spacer layer having one surface adjacent at least one of the reflective sections;
an intake reflector which is at least partially transmissive to at least the first band of wavelengths and the second band of wavelengths on an opposing surface of the first spacer layer; and
a second spacer layer between the at least two reflective sections.

13. The apparatus as set forth in claim 1 wherein the first band of wavelengths is substantially non-overlapping with the second band of wavelengths.

14. The apparatus as set forth in claim 1 further comprising at least one condensing lens apparatus positioned to converge the solar radiation on the reflector assembly.

15. The apparatus as set forth in claim 14 wherein the at least one condensing lens assembly further comprises a Fresnel microstructure optically configured to converge at least a portion of the solar radiation on the reflector assembly.

16. The apparatus as set forth in claim 15 further comprising at least a third one of the two or more solar conversion cells, the third one of the two or more solar conversion cells is responsive to a third band of wavelengths from solar radiation, wherein the Fresnel microstructure in the at least one condensing lens assembly is further optically configured to converge at least a portion of the third band of wavelengths on to the third one of the two or more solar conversion cells.

17. The apparatus as set forth in claim 16 wherein the first band of wavelengths, the second band of wavelengths and the third band of wavelength are substantially non-overlapping with respect to each other.

18. The apparatus as set forth in claim 1 wherein the one of the two or more solar conversion cells positioned closer to a first incident location for receiving the solar radiation is responsive to a shorter band of wavelengths than the other of the two or more solar conversion cells positioned further from the first incident location.
